(19) United States
(12) Patent Application Publication
(10) Pub. No.: US 2006/0151208 A1
(43) Pub. Date: Jul. 13, 2006

(54) Use of laminated materials for shielding from electromagnetic waves

(76) Inventor: Wolfgang Greiser, Neusass (DE)

Correspondence Address: JOHNS MANVILLE INTERNATIONAL, INC., 717 SEVENTEENTH STREET, DENVER, CO, 80202, US

(21) Appl. No.: 11/315,736

(22) Filed: Dec. 22, 2005

(30) Foreign Application Priority Data
Jan. 7, 2005 (DE) 102005001063.6-35

(51) Int. Cl. H05K 9/00

(52) U.S. Cl. 174/388; 174/350

(57) ABSTRACT

The present invention relates to the use of a laminated material for shielding from electromagnetic waves, whereby the laminated material includes at least one layer comprising fibres and at least one aluminum layer and the aluminum layer has a thickness of at least 10 μm.

### BACKGROUND OF THE INVENTION

The present invention relates to the use of a laminated material for shielding from electromagnetic waves, whereby the laminated material includes at least one layer comprising fibres and at least one aluminum layer.

Shielding from electromagnetic waves is becoming increasingly important, since the latter are becoming increasing prevalent. It should be taken into account here that the use of mobile telephones, in particular cellular phones, is widespread. On the other hand, there is increasingly less acceptance of the base stations required for this on account of the irradiation of electromagnetic waves. In this connection, it should be placed on record that, depending on the intensity, electromagnetic waves, especially in the range from several megahertz up to gigahertz, can have harmful effects on health. This problem is discusses especially under the keyword “electrosmog”.

For these reasons, the buildings on which the transmission masts of the base stations are installed, in particular, as well as the buildings in the surrounding area need to be shielded against the effect of electromagnetic waves.

Materials for shielding from electromagnetic waves are known per se. Utility model DE20215027, for example, thus describes a textile surface structure for shielding from electromagnetic waves. The teaching set forth therein, however, is only inadequately described. Thus, there are no explanations concerning the exact materials and the composition of the laminated materials described therein. In particular, a description as to which of the components should be of a metallic type is absent, as is an explanation concerning the metals to be used. In particular, the layer thickness of the further layer that may possibly be used is also absent.

Furthermore, specification US-A-2002/0148626 describes the use of laminated materials for the absorption of electromagnetic waves above a wavelength of 1 GHz. The materials desribed in US 2002/0148626 comprise two layers, whereby one layer is a nonwoven fabric, which includes both non-metallic and metallic fibres. The second layer is a metallic layer, which can reflect electromagnetic waves. The thickness of the respective layers is not disclosed in US 2002/0148626. On the other hand, the requirement emerges from the examples that the nonwoven fabric layer includes a certain proportion of metallic fibres. If the proportion of metallic fibres diminishes, the absorption of the electromagnetic waves fall significantly. The same applies if the proportion of metallic fibres is too high.

A drawback with the laminated materials described in US 2002/0148626 is, in particular, their expensive method of production. In particular, a high proportion of metallic fibres is required, which on the one hand makes the laminated materials very expensive, and on the other hand has an adverse effect on the processability and the mechanical properties. Moreover, the metallic fibres can oxidize, as a result of which the durability of the materials is adversely affected.

The problem of the present invention, therefore, is to provide materials absorbing electromagnetic waves, said materials being able to be produced particularly easily. The materials to be used should therefore be obtainable on a large scale and cost-effectively. Moreover, the materials that absorb the electromagnetic waves should be able to be produced on a large scale.

Furthermore, it was the problem of the present invention to specify laminated materials which have a particularly high mechanical stability. Moreover, the laminated materials should have a long useful life.

The problems set out above are solved by the use with all the features of claim 1. Preferred embodiments of the use according to the invention are protected in claims 2 to 16.

### SUMMARY OF THE INVENTION

Due to the fact that the aluminum layer of a laminated material, including at least one layer comprising fibres and at least one aluminum layer, has a thickness of least 10 μm, it is possible to provide a laminated material for shielding from electromagnetic waves that can be produced cost-effectively on a large scale.

Furthermore, the following advantages are obtained through the present invention:

The laminated materials to be used can be used for the sealing of roofs.

The laminated material to be used have excellent mechanical properties.

Furthermore, these materials have a long useful life.

The production of the laminated materials to be used can be carried out on conventional plant.

The laminated materials to be used can be processed simply on a large scale.

The laminated materials to be used exhibit excellent shielding from electromagnetic waves over a large frequency range.

The laminated materials to be used include at least one layer comprising fibres. Such layers comprising fibres are known per se. They include, amongst others, woven fabrics, knitted fabrics, plaited fabrics, fibre bundles and nonwoven fabrics.

### DESCRIPTION OF THE PREFERRED EMBODIMENTS

The layer comprising fibres is particularly preferably a nonwoven fabric. The layer comprising fibres particularly preferably comprise plastic fibres. The plastics suitable for this include in particularly polyamides, polyvinyl alcohol or polyesters. The layer comprising fibres particularly preferably comprises polyester fibres, in particularly polyethylene terephthalate, polybutylene terephthalate and polytrimethyl terephthalate.

The use of metallic fibres in the layer comprising fibres is not necessary to achieve the shielding from electromagnetic waves. Since the use of such fibres is bound up with many drawbacks, the layer comprising fibres preferably includes at most 5 weight percent, particularly preferably at most 1 weight percent metallic fibres. According to a very particularly preferred aspect of the present invention, the layer comprising fibres does not include a measurable proportion of metallic fibres.

The layer comprising fibres, in particular the nonwoven fabrics, can be reinforced. The reinforcement can take place mechanically, thermally or by the use of binders. The steps required for this are known to the person skilled in the art. Thus, the reinforcement can take place mechanically by needle loom, thermally by bonding of the fibres which have become soft at the surface in the heat. All the reinforcement methods can be used respectively on their own or in combination with one or more of the other reinforcement methods, as it known in the prior art.

The layer comprising fibres preferably has a thickness in the range from 0.4 to 2 mm.

The layer comprising fibres can have a weight per unit area in the range from 100-400 g/m², particularly preferably from 150-300 g/m².

An aluminum layer, for example an aluminum foil, is applied on at least one side of the layer comprising fibres. The aluminum layer has a thickness of at least 10 μm, preferably at least 13 μm and very particularly preferably at least 14 μm.

The aluminum layer preferably has a thickness of at most 150 μm, particularly preferably at most 100 μm and very particularly preferably at most 50 μm.

Aluminum layers that can be used according to the invention are known per se, whereby this layer can include other constituents apart from aluminum. The proportion of aluminum preferably amounts to at least 50 wt. %, particularly preferably at least 80 wt. % and very particularly preferably at least 98 wt %, related to the weight of the aluminum layer.

The aluminum layer preferably has a conductivity in the range from 0.34*10⁸ to 0.38*10⁸ S/m, particularly preferably approx. 0.37*10⁸ S.m.

The aluminum layer can preferably be designed as a foil, whereby other forms, for example as woven fabric or as nonwoven fabric, are also possible.

The aluminum layer can preferably be in contact with the layer comprising fibres, whereby the connection of the aluminum layer and the layer comprising fibres is known among experts. The latter can take place for example mechanically or by means of a binder.

The aluminum layer can have an expansion reserve in at least one direction in the range from 2-35%, preferably 3-30% and particularly preferably 10-20%, related to the length of the layer comprising fibres in this direction. As a result of this advantageous development, the laminated material to be used according to the invention can be provided with a bitumen layer, as a result of which the latter can be used as roof sheeting. Such particularly preferred laminated materials are described in particular in DE-A-2827136.

Both the aluminum layer and the layer comprising fibres, in particular a nonwoven fabric, can preferably be provided with a perforation, which can originate from needling with a needle loom or with a needle perforation machine. This perforation can serve for better penetration of adhesive and bitumen into the nonwoven fabric as well as a gas permeability of the nonwoven fabric and the metal foil.

Preferably, at least the aluminum layer includes a perforation, whereby the perforated area can amount to between 8 and 15%, in particular between 10 and 15% of the surface area of the layer comprising fibres.

According to a particular aspect of the present invention, the material layer has a weight per unit area in the range from 220 to 250 g/m².

According to a particular aspect of the present invention, the laminated material to be used can be provided with a bitumen layer in order to serve as roof sheeting. Bituminized roof sheeting as well as the process steps required for this are widely known among experts, whereby this is described for example in Offenlegungsschrift DE-A-2827136 and utility model G 9101083.7 with filing date Jan. 31, 1991.

The bitumen used is known, whereby air-blown or modified bitumen can be used. The bitumen can be modified with rubber, in particular with atactic polypropylene. Furthermore, the bitumen can contain flame-retarding substances. The coating of bitumen can have the same or a different thickness on the two sides of the laminated material.

According to a particular aspect, the aluminum layer can be earthed.

The present invention is described below with the aid of an example, this not being intended to give rise to any limitation.

### EXAMPLE 1

A polyester nonwoven fabric provided with an aluminum layer (nonwoven fabric type 053/250 g/m², commercially available from Johns Manville under the trade name (DuraSpun), was measured in the frequency range from 220 Hz to 10 GHz with linearly polarized waves using the procedure according to IEEE STD 299-1997. For this purpose, the textile sample to be tested was placed in front of a 80 cm×60 cm opening of a metal wall (area 210 cm×200 cm). It was ensured that the material sample had contact over the whole area with the metal plate of the measurement set-up. The sample was rotated through 900 degrees for the measurement of the different polarizations. After calibration of the measuring distance, the shield attenuation of the test object—resulting from the frequency bands of the measuring antennas in two frequency bands—was carried out:
Range 1: 220 MHz to 2,200 MHz
Range 2: 1 GHz to 10 GHz

The tips of the logarithmic-periodic measuring antennas were positioned according to IEE STD 299-1997 in each case 30 cm in front of and behind the test piece. The following measuring instruments were used:
Vectorial network analyser type 360 (40 MHz to 18.6 GHz), Firm Wiltron Measuring antennas: Bilog-Antenna, type CBL 6112A (30 MHZ to 2,00 MHz),
Firm Case
Measuring antennas: Logper-Antennas, type HL025 (1 GHz to 18 GHz), Firm Rohde and Schwarz.

Above 500 MHz, the shield attenuation stood at almost 50 dB, that means that 99.999% of the occurring output is shielded, only 0.001% penetrating.

These excellent values apply both to signals of the mobile phone network in the D network (900 MHz) and in the E network (1800 MHz). At the upper measured frequency margin, the attenuation still stands at an excellent approx. 47 dB.

What is claimed is:

1. Use of a laminated material for shielding from electromagnetic waves, whereby the laminated material includes at least one layer comprising fibres and at least one aluminum layer, characterized in that the aluminum layer has a thickness of at least 10 μm.

2. The use according to claim 1, characterized in that the layer comprising fibres is a nonwoven fabric.

3. The use according to claim 1 or 2, characterized in that the layer comprising fibres includes at least one binder.

4. The use according to any one of the preceding claims, characterized in that the layer comprising fibres comprises polyester fibres.

5. The use according to any one of the preceding claims, characterized in that the layer comprising fibres includes at most 1 wt. % metallic fibres.

6. The use according to any one of the preceding claims, characterized in that the layer comprising fibres has a weight per unit area in the range from 100 to 400 g/m².

7. The use according to any one of the preceding claims, characterized in that the aluminum layer has a thickness of at least 13 μm.

8. The use according to any one of the preceding claims, characterized in that the aluminum layer is in contact with the layer comprising fibres.

9. The use according to any one of the preceding claims, characterized in that the aluminum layer is earthed.

10. The use according to any one of the preceding claims, characterized in that the aluminum layer has a conductivity of 0.37*10⁸ S/m.

11. The use according to any one of the preceding claims, characterized in that the electromagnetic waves have a frequency in the range from 500 MHz to 18 GHz.

12. The use according to any one of the preceding claims, characterized in that the layer comprising fibres has a thickness in the range from 0.4 to 2 mm.

13. The use according to any one of the preceding claims, characterized in that the laminated material has a weight per unit area in the range from 220 to 250 g/m².

14. The use according to any one of the preceding claims, characterized in that the aluminum layer has an expansion reserve in at least one direction in the range from 2 to 35%, related to the length of the layer comprising fibres in this direction.

15. The use according to any one of the preceding claims, characterized in that the aluminum layer has a perforation.

16. The use according to claim 15, characterized in that the perforated area amounts to between 8 and 15%, in particular between 10 and 15%, of the surface area of the layer comprising fibres.
